(19) United States
(12) Patent Application Publication
(10) Pub. No.: US 2017/0202094 A1
(43) Pub. Date: Jul. 13, 2017

(54) DISPLAY DEVICE

(71) Applicant: SAMSUNG DISPLAY CO., LTD., Yongin-si (KR)

(72) Inventor: Sangwoo Kim, Cheonan-si (KR)

(21) Appl. No.: 15/237,487

(22) Filed: Aug. 15, 2016

(30) Foreign Application Priority Data
Jan. 8, 2016 (KR) 10-2016-0002739

(51) Int. Cl. H05K 5/00; H05K 1/02; H01L 51/52; H05K 7/14; H05K 5/02

(52) U.S. Cl. CPC H05K 5/0017; H05K 7/14; H05K 5/0243; H01L 51/5237; H05K 1/0271; H05K 2201/10128

(57) ABSTRACT

A display device includes a display panel including a flat area and a curved area extending from the flat area in a bent manner, a flat shock absorbing member below the flat area and overlapping the flat area, a curved shock absorbing member below the curved area and overlapping the curved area, and a hard coating member below the flat shock absorbing member.

### CROSS-REFERENCE TO RELATED APPLICATION

This application claims priority to and the benefit of Korean Patent Application No. 10-2016-0002739, filed on Jan. 8, 2016, in the Korean Intellectual Property Office, the disclosure of which is incorporated herein in its entirety by reference.

### BACKGROUND

1. Field

Embodiments of the present disclosure relate to a display device including a cover member.

2. Description of the Related Art

Mobile devices are being widely used. A mobile device may include a display panel that displays an image and a circuit board that provides driving signals used for displaying the image. The circuit board is attached to the rear surface of the display panel and may be electrically connected to the display panel through a flexible printed circuit board.

During the process of attaching the circuit board to the rear surface of the display panel, an indentation caused by attaching the circuit board to the rear surface of the display panel may be formed. Such an indentation may be visible to a user.

### SUMMARY

According to one or more example embodiments of the present disclosure, a display device includes a cover member that can prevent an indentation from being formed on the rear surface of the display panel.

According to one or more example embodiments of the present disclosure, a display device includes a display panel including a flat area and a curved area extending from the flat area in a bent manner, a flat shock absorbing member below the flat area and overlapping the flat area, a curved shock absorbing member below the curved area and overlapping the curved area, and a hard coating member below the flat shock absorbing member.

In an embodiment, a circuit board may be below the hard coating member. The circuit board may be configured to provide a driving signal to the display panel.

In an embodiment, the hard coating member may be partially overlapped with the flat area.

In an embodiment, the flat area may include a display area to display an image, and a non-display area that is adjacent to the display area, wherein the circuit board overlaps the display area.

In an embodiment, a light blocking member may be below the display panel, wherein a portion of the light blocking member is between the display panel and the flat shock absorbing member, and another portion of the light blocking member is between the display panel and the curved shock absorbing member.

In an embodiment, a first adhesive tape may be between the flat area and the flat shock absorbing member, the first adhesive tape including a base layer having a top surface and a rear surface, a first adhesive layer on the top surface, the first adhesive layer including a polymer bead, and a second adhesive layer on the rear surface.

In an embodiment, a second adhesive tape may be connected to the first adhesive tape and located between the curved area and the curved shock absorbing member.

In an embodiment, the flat shock absorbing member may have a first thickness and the curved shock absorbing member may have a second thickness, the second thickness being greater than the first thickness.

In an embodiment, the hard coating member may have a third thickness, the first thickness being greater than the third thickness.

In an embodiment, a hardness of the flat shock absorbing member may be greater than a hardness of the curved shock absorbing member.

The curved area may include a first curved area and a second curved area, that are opposite each other, with the flat area therebetween.

The curved shock absorbing member may include a first curved shock absorbing member below the first curved area and a second curved shock absorbing member below the second curved area.

A display device includes a display panel including a flat area and a curved area extending from the flat area in a bent manner, a flat shock absorbing member having a first thickness, the flat shock absorbing member being located below the flat area and overlapping the flat area, and a curved shock absorbing member having a second thickness, the curved shock absorbing member being located below the curved area and overlapping the curved area, the first thickness is greater than the second thickness, and a hardness of the flat shock absorbing member is greater than a hardness of the curved shock absorbing member.

In an embodiment, a first adhesive tape may be between the flat area and the flat shock absorbing member, the first adhesive tape including a base layer having a top surface and a rear surface, a first adhesive layer on the top surface, and a second adhesive layer on the rear surface, wherein the first adhesive layer includes a polymer bead.

In an embodiment, a second adhesive tape may be connected to the first adhesive tape and located between the curved area and the curved shock absorbing member.

In an embodiment, a hard coating member may be below the flat shock absorbing member.

In an embodiment, the hard coating member may partially overlap the flat area.

### BRIEF DESCRIPTION OF THE FIGURES

These and/or other aspects will become apparent and more readily appreciated from the following description of the embodiments, taken in conjunction with the accompanying drawings in which:

FIG. 1 is a perspective view of a display device according to one or more example embodiments of the inventive concept;

FIG. 2 is an exploded perspective view of a display device according to one or more example embodiments of the inventive concept;

FIG. 3 is a cross-sectional view taken along the line I-I′ in FIG. 1;

FIG. 4 is a cross-sectional view taken along the line II-II′ in FIG. 2;

FIG. 5 is a cross-sectional view of the adhesive tape illustrated in FIG. 4;

FIG. 6 is a plan view illustrating a rear surface of a module according to one or more example embodiments of the inventive concept, in which a shock absorbing member, a curved shock absorbing member, and a hard coating member illustrated in FIG. 4 are coupled;

FIG. 7 is a plan view illustrating a rear surface of a module according to one or more example embodiments of the inventive concept, in which the shock absorbing member, the curved shock absorbing member, and the hard coating member illustrated in FIG. 4 are coupled; and

FIG. 8 is a cross-sectional view taken along the line II-II′ in FIG. 2, according to one or more example embodiments of the present invention.

### DETAILED DESCRIPTION

Features of the inventive concept and methods of accomplishing the same may be understood more readily by reference to the following detailed description of embodiments and the accompanying drawings. Hereinafter, example embodiments will be described in more detail with reference to the accompanying drawings, in which like reference numbers refer to like elements throughout. The present invention, however, may be embodied in various different forms, and should not be construed as being limited to only the illustrated embodiments herein. Rather, these embodiments are provided as examples so that this disclosure will be thorough and complete, and will fully convey the aspects and features of the present invention to those skilled in the art. Accordingly, processes, elements, and techniques that are not necessary to those having ordinary skill in the art for a complete understanding of the aspects and features of the present invention may not be described. Unless otherwise noted, like reference numerals denote like elements throughout the attached drawings and the written description, and thus, descriptions thereof will not be repeated. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments only and is not intended to be limiting of the present invention. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

The electronic or electric devices and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the exemplary embodiments of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

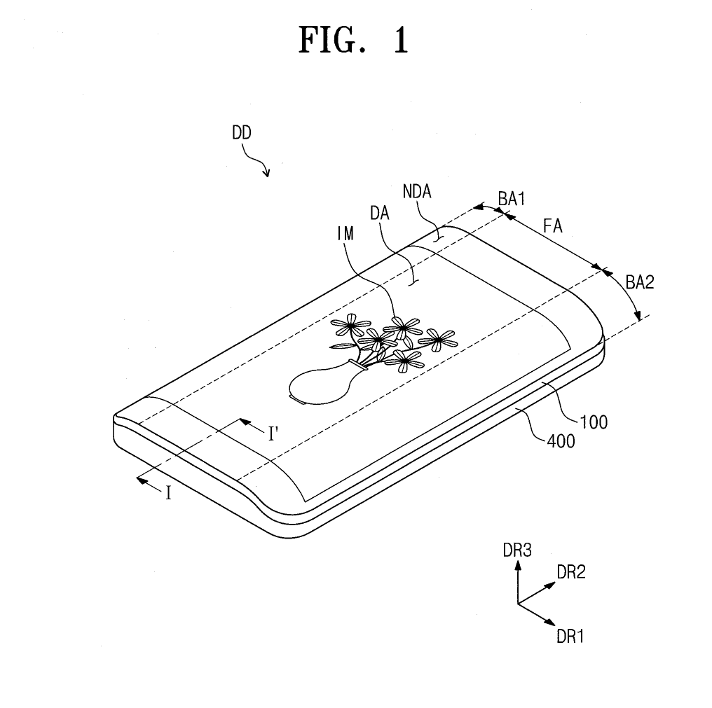

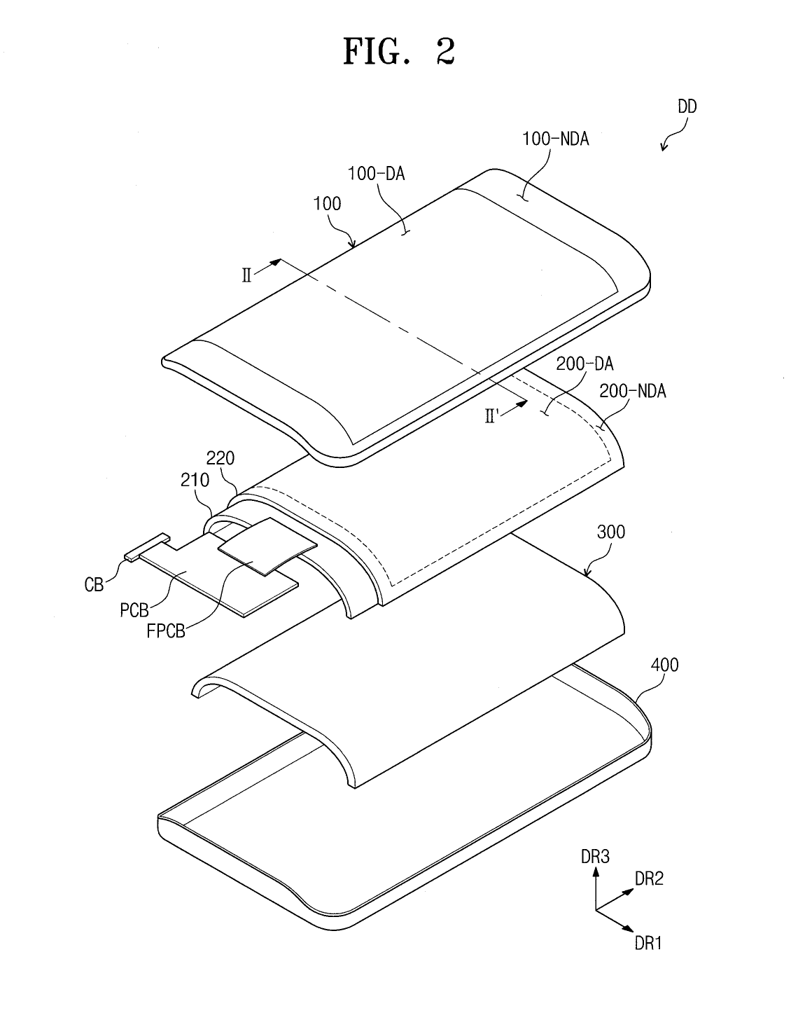

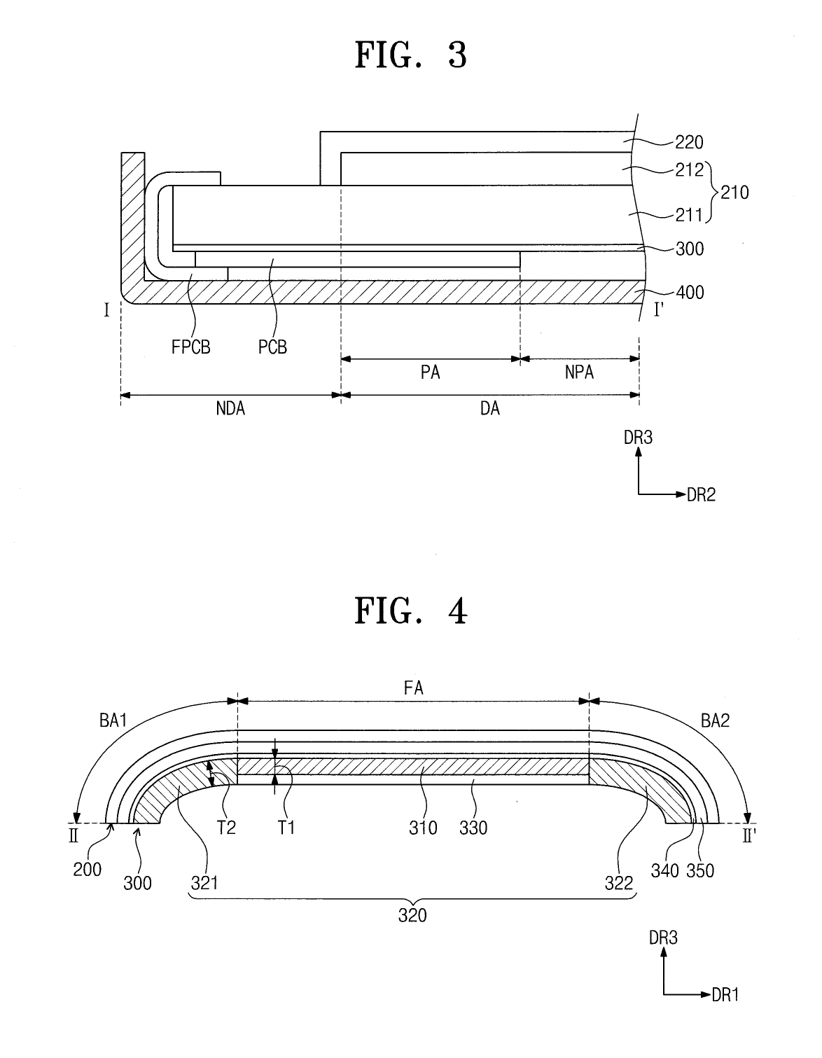

FIG. 1 is a perspective view of a display device according to an embodiment of the inventive concept. FIG. 2 is an exploded perspective view of the display device according to an embodiment of the inventive concept. FIG. 3 is a cross-sectional view taken along the line I-I′ in FIG. 1.

In FIG. 1, for example, the display device according to an embodiment of the inventive concept is illustrated as being used in a mobile device. The mobile device may include a tablet PC, a smartphone, a personal digital assistant (PDA), a portable multimedia player (PMP), a gaming device, a wristwatch type electronic device, and/or the like. However, the inventive concept is not limited thereto. One or more example embodiments of the inventive concept may be used in a large scale electronic device, such as a television or a billboard, and may also be used in a small or medium scale electronic device, such as a personal computer, a notebook computer, a vehicle navigation unit, or a camera. These are provided merely as exemplary embodiments, and one or more exemplary embodiments of the inventive concept may be used in other electronic devices without deviating from the scope of the inventive concept.

As illustrated in FIG. 1, the display device DD includes a plurality of areas that are divided on a display surface. The display device DD includes a display area DA that displays an image IM, and a non-display area NDA adjacent to the display area DA. The non-display area NDA may surround the display area DA.

According to one or more embodiments of the inventive concept, the display device DD may have a partially curved shape. The display device DD may include a flat area FA and curved areas BA1 and BA2 that are connected to the flat area FA and are curved.

The flat area FA is parallel to a plane defined by a first direction DR1 and a second direction DR2, and the normal direction to the flat area FA indicates a third direction DR3. The third direction DR3 is a reference direction that distinguishes, in each of the members (or components) of the display device DD, the front surface from the rear surface. However, a direction indicated by the directions is a relative concept and may be converted into another direction in accordance with the orientation of the display device DD.

The curved areas BA1 and BA2 may include a first curved area BA1 and a second curved area BA2. The first curved area BA1 and the second curved area BA2 may be positioned to be opposite (or to face) each other along a first direction, with the flat area FA therebetween. The first curved area BA1 and the second curved area BA2 may be parallel to each other. Moreover, the first curved area BA1 and the second curved area BA2 are illustrated as extending in the second direction DR2. Meanwhile, the first and second curved areas BA1 and BA2, by way of example, are illustrated as being composed of two curved areas, but the present inventive concept is not limited thereto. For example, the display device DD may include only one curved area, either the first curved area BA1 or the second curved area BA2.

A portion of the display area DA may be located on the flat area FA, and another portion may be located on the first and second curved areas BA1 and BA2. In an embodiment, the display area corresponding to the flat area FA is illustrated as displaying the image IM.

Referring to FIGS. 1 to 3, the display device DD includes a window member (or a window) 100, a display panel 200, a cover member (or a cover) 300, and a case 400. Meanwhile, the display device illustrated in FIG. 3 is shown without the window member 100, for the convenience of description.

For example, each of the window member 100, the display panel 200, and the cover member 300 may have a partially curved shape. Each of the window member 100, the display panel 200, and the cover member 300 may include a flat area and a curved area. According to one or more example embodiments, the flat area in each of the window member 100, the display panel 200, and the cover member 300 corresponds to the flat area FA in the display device DD, and the curved areas in each of the window member 100, the display panel 200, and the cover member 300 correspond to the first and second curved areas, BA1 and BA2, respectively, in the display device DD. For example, the flat area FA and the first and second curved areas BA1 and BA2 may be used to indicate the flat area and the curved area in each of the window member 100, the display panel 200, and the cover member 300.

Meanwhile, according to the below description, the flat area FA indicated in each drawing refers to the flat area FA in the display panel 200, and the first and second curved areas, BA1 and BA2, respectively, refer to the first and second curved areas BA1 and BA2 in the display panel 200.

The window member 100 includes a display 100-DA that transmits the image IM provided by the display panel 200 and a non-display area 100-NDA that surrounds the display area 100-DA.

The window member 100 may be positioned on the display panel 200. According to one or more example embodiments, the window member 100 may include a cover window made of glass, sapphire, plastic, and/or the like.

The display panel 200 includes a display area 200-DA and a non-display area 200-NDA. The display area 200-DA is an area that displays the image IM and corresponds to the display area 100-DA in the window member 100. The non-display area 200-NDA surrounds the display area 200-DA and corresponds to the non-display area 100-NDA in the window member 100.

The display panel 200 may include a display layer 210, an organic light emitting diode, and an encapsulation layer 220. The organic light emitting diode is located at the display layer 210. The encapsulation layer 220 located on the display layer 210 and seals the organic light emitting diode from the outside.

For example, the display layer 210 may include an array substrate 211 and a display member 212. The array substrate 211 may include a plurality of pixels arranged to correspond to the display area DA, and a plurality of signal lines respectively connected to the pixels. In one or more example embodiments, the signal lines extend in the second direction DR2 and include a plurality of gate lines arranged in the first direction DR1. In one or more example embodiments, the signal lines may extend in the first direction DR1 and include a plurality of data lines arranged in the second direction DR2. The gate lines and the data lines, respectively cross while being insulated from each other.

However, the technical concept of an embodiment of the inventive concept is not limited thereto, and the gate lines may extend in the first direction DR1 and be arranged along the second direction DR2. Moreover, the data lines may extend in the second direction DR2 and be arranged along the first direction DR1.

The pixels are arranged in a matrix shape defined by the first direction DR1 and the second direction DR2. The pixels are respectively connected to corresponding gate lines and the corresponding data lines. The pixels receive an electrical signal from the corresponding gate line and the corresponding data line to generate the image.

The display member 212 is located on the array substrate 211. The display member 212 includes a display element. According to one or more example embodiments, the display member 212 may include various display elements. For example, the display element may be a liquid crystal capacitor, an organic light emitting diode, an electrophoretic element, or an electrowetting element. The display element according to one or more example embodiments of the inventive concept may be described as a plurality of organic light emitting diodes. Therefore, the display device DD according to one or more example embodiments of the inventive concept may be an organic light emitting display device that contains an organic light emitting display panel.

An organic light emitting diode includes a first electrode, an organic light emitting layer, and a second electrode. The first electrode may be an anode or a positive electrode. The second electrode may be a negative electrode or a cathode. The first electrode generates holes and the second electrode generates electrons. The holes and the electrons are injected into the organic light emitting layer from the first electrode and the second electrode, respectively. Excitons are formed as the holes and the electrons are combined in the organic light emitting layer, and light is emitted when the excitons fall from an excited state to a ground state.

The display panel 200 may have a display surface that displays images IM1 and IM2, and a rear surface that is opposite the display surface. In FIG. 2, the display surface is the top surface of the encapsulation layer 220, and the rear surface is defined as the rear surface of the display layer 210.

The display device DD may further include a touch panel. The touch panel may be located between the window member 100 and the display panel 200. However, the touch panel according to one or more example embodiments of the inventive concept is not limited thereto and may be located inside of the display panel 200. The touch panel may operate in a resistance film mode, a capacitance mode, or an electromagnetic induction mode, and obtain the coordinate information of the position at which a touch event is generated.

The cover member 300 may be attached to the rear surface of the display panel 200. The cover member 300, in a coupled state, may be located between the display panel 200 and a printed circuit board PCB. A detailed description of the cover member 300 is given below.

The case 400 is coupled to the window member 100 to accommodate the display panel 200 and the cover member 300. The case 400 may include plastic or metal. In one or more example embodiments of the inventive concept, the case 400 may be excluded.

Moreover, the display device DD may further include a flexible printed circuit board FPCB and the printed circuit board PCB.

The flexible printed circuit board FPCB may electrically connect the printed circuit board PCB to the display panel 200. An end of the flexible printed circuit board FPCB may be connected to a surface of the display layer 210 that is exposed by the encapsulation layer 230, and the other end may be connected to the printed circuit board PCB. The flexible printed circuit board FPCB is flexible, and in a coupled state, may be bent below the cover member 300.

The printed circuit board PCB may output a signal to the display panel 200 or receive a signal from the display panel 200 through the flexible printed circuit board FPCB. Due to the bending of the flexible printed circuit board FPCB, the printed circuit board PCB may be attached in a coupled state to the bottom of the cover member 300. A connector CB for receiving a signal from the outside may be connected to the printed circuit board PCB.

According to an embodiment of the inventive concept, the printed circuit board PCB may be located on the rear surface (or bottom surface) of the cover member 300 and overlap the flat area FA in the display panel 200. As illustrated in FIG. 3, the printed circuit board PCB may partially overlap portions of the non-display area NDA and the display area DA. Here, an area in which the printed circuit board PCB overlaps the display area DA in the flat area FA is defined as a disposed area PA, and an area in which the printed circuit board PCB does not overlap the display area DA in the flat area FA is defined as the non-disposed area NPA.

Meanwhile, in a process of attaching the printed circuit board PCB to the rear surface of the cover member 300, pressure may be applied in the third direction DR3 by the printed circuit board PCB. Thereby, an indentation may be formed on the rear surface of the display panel 200. Here, the indentation may indicate a portion (e.g., a predetermined portion) that partially protrudes in the third direction DR3.

According to one or more example embodiments of the inventive concept, the cover member 300 may be on the rear surface of the display panel 200 to prevent or substantially prevent the indentation from being formed when attaching the printed circuit board PCB. The cover member 300 according to an embodiment of the inventive concept may include a hard coating member located on an area to which the printed circuit board PCB is attached. A more detailed description of the cover member 300 that includes the hard coating member will be provided in reference to FIG. 4.

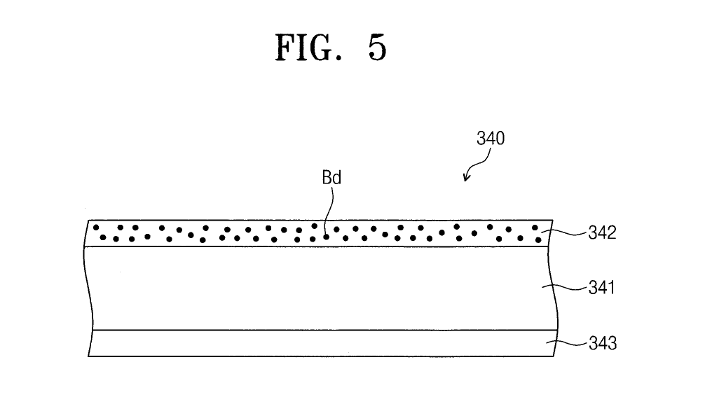

FIG. 4 is a cross-sectional view taken along the line II-II′ in FIG. 2. FIG. 5 is a cross-sectional view of the adhesive tape illustrated in FIG. 4.

For convenience, the cross-sectional view illustrated in FIG. 4 excludes the configuration of the window member 100 and the case 400, and is a cross-sectional view illustrating the configuration of the display panel 200 and the cover member 300.

For example, referring to FIGS. 2 and 4, the cover member 300 according to one or more example embodiments includes a flat shock absorbing member 310, a curved shock absorbing member 320, a hard coating member 330, and an adhesive tape 340.

The flat shock absorbing member 310 may be located on the rear surface of the display panel 200 and may overlap the flat area FA of the display panel 200. As viewed in a plane, the flat shock absorbing member 310 may be located on the rear surface of the display panel 200 and may have a smaller or equal surface area to the flat area FA. In an embodiment, the flat shock absorbing member 310 may have a first thickness T1.

The flat shock absorbing member 310 may absorb a portion of the shock that is respectively applied to the flat area FA in the display panel 200 and the flat area in the window member 100 (see FIG. 2). Thus, the flat shock absorbing member 310 may prevent the flat area FA in the display panel and the flat area in the window member 100 from being damaged.

According to an embodiment, the flat shock absorbing member 310 may be made of a polymer resin (e.g., polyurethane, polycarbonate, polypropylene, and/or polyethylene), or may be formed as a sponge through foam molding of a rubber solution, a urethane based material, and/or an acrylic based material.

The curved shock absorbing member 320 may include a first curved shock absorbing member 321 and a second curved shock absorbing member 322, and may be on (or at) the same layer as the flat shock absorbing layer 310. The first and second curved shock absorbing members 321 and 322 may respectively overlap the first and second curved areas BA1 and BA2 in the display panel 200. According to one or more embodiments of the inventive concept, each of the first and second curved shock absorbing members 321 and 322 may have a second thickness T2. Here, the second thickness T2 may be greater than the first thickness T1.

According to one or more example embodiments, each of the first and second curved shock absorbing members 321 and 322 may be made of a polymer resin (e.g., polyurethane, polycarbonate, polypropylene, or polyethylene), or may be formed as a sponge through foam molding of a rubber solution, a urethane based material, and/or an acrylic based material.

The first and second curved shock absorbing members 321 and 322 may respectively absorb a portion of the shock that is applied to the first and second curved areas BA1 and BA2 in the display panel 200, and the curved area in the window member 100. Thus, the curved shock absorbing member 320 may prevent the first and second curved areas BA1 and BA2 in the display panel 200 and the curved area in the window member 100 from being damaged.

For example, the first curved shock absorbing member 321 and the second curved shock absorbing member 322 may be opposite (or face) each other, with the flat shock absorbing member 310 therebetween. Each of the first curved shock absorbing member 321 and the second curved shock absorbing member 322 may have a shape that extends in the second direction DR2. The first curved shock absorbing member 321 may be located below the first curved area BA1 and may be connected to a side wall of the flat shock absorbing member 310. However, the technical concept of the inventive concept is not limited thereto, and the first curved shock absorbing member 321 may be located below the first curved area BA1 without being connected to the flat shock absorbing member (or the flat shock absorber) 310.

The second curved shock absorbing member 322 may be located below the second curved area BA2 in the display panel 200, and may be connected to another sidewall of the flat shock absorbing member 310. However, the technical concept of the inventive concept is not limited thereto, and the second curved shock absorbing member 322 may be located below the second curved area BA2 without being connected to the flat shock absorbing member 310.

According to one or more example embodiments, the hardness of the flat shock absorbing member 310 may be greater than the hardness of each of the first and second curved shock absorbing members 321 and 322.

The hard coating member 330 may be located below the flat shock absorbing member 310 so as to overlap the flat area FA at the display panel 200. Moreover, the hard coating member 330 may be thinner than the flat shock absorbing member 310.

As illustrated in FIG. 3, the printed circuit board PCB may be located below the hard coating member 330. Meanwhile, in a process of attaching the printed circuit board PCB to the bottom of the hard coating member 330, a pressure (e.g., predetermined pressure) may be applied in the third direction DR3 to the rear surface of the display panel 200. In this case, transfer of the pressure in the third direction DR3 to the printed circuit board PCB may be prevented or reduced by the hard coating member 330. That is, due to the hard coating member 330 having hardness (e.g., predetermined hardness) and being located on the rear surface of the display panel 200, application of the pressure to the rear surface of the display panel 200 may be prevented or reduced.

According to one or more example embodiments of the inventive concept, the hard coating member 330 may be composed of polyimide (PI), polyethylene naphthalate (PEN), polyethylene terephthalate (PET), fiber-reinforced plastic (FRP), polyethersulfone (PES), polyarylate (PAR), and/or polycarbonate (PC). However, the technical concept according to the inventive concept is not limited thereto, and the hard coating member 330 may be composed of various other suitable materials.

A portion of the adhesive tape 340 may be located between the flat shock absorbing member 310 and the flat area FA, and may attach the flat shock absorbing member 310 and the flat area FA to each other. Another portion of the adhesive tape 340 may be located between the first curved shock absorbing member 321 and the first curved area BA1, and between the second curved shock absorbing member 322 and the second curved area BA2. Such another portion of the adhesive tape 340 may attach the first curved shock absorbing member 321 to the first curved area BA1, and attach the second curved shock absorbing member 322 to the second curved area BA2.

For example, as illustrated in FIG. 5, the adhesive tape 340 includes a base layer 341, a first adhesive layer 342, and a second adhesive layer 343.

The base layer 341 may include a top surface on which the first adhesive layer 342 is located, and a rear surface on which the second adhesive layer 343 is located. The first adhesive layer 342 may be located between the display panel 200 and the base layer 341, and the second adhesive layer 343 may be located between the base layer 341 and the cover member 300.

According to one or more example embodiments of the inventive concept, the first adhesive layer 342 may include a plurality of polymer beads Bd. In an embodiment, the polymer beads Bd are described as including silica or polymethyl methacrylate, but the polymer beads Bd may include various other suitable materials. The polymer beads Bd may block light from being reflected, and may prevent light from being transmitted. Thus, when the indentation is present in the rear surface of the display panel 200, the indentation may not be visible due to the plurality of polymer beads Bd included in the first adhesive layer 342.

As described above, the hard coating member 330 may be located on the rear surface of the display panel 200. In this case, when the printed circuit board PCB is attached to the bottom of the hard coating member 330, a pressure (e.g., a predetermined pressure) may be applied in the third direction DR3 on the rear surface of the display panel 200. However, when attaching the printed circuit board PCB, the pressure, which is applied in the direction of the rear surface of the display panel 200, may be prevented by the hard coating member 330 from being transferred to the rear surface of the display panel 200. Thereby, the indentation in the rear surface of the display panel 200 may be prevented or substantially prevented.

Moreover, as described above, the adhesive tape 340 according to one or more example embodiments of the inventive concept may include the polymer beads Bd. Therefore, due to the polymer beads Bd, even when the indentation is present at the rear surface of the display panel 200, such an indentation at the rear surface of the display panel 200 may not be visible.

The cover member 300 may further include a light blocking member 350. A portion of the light blocking member 350 is located between the flat area of the display panel 200 and the flat shock absorbing member 310. Another portion of the light blocking member 350 may be located between the first and second curved areas BA1 and BA2 of the display member 212 and the curved shock absorbing member 320. The light blocking member 350 is attached to the rear surface of the display panel 200 to block the light incident on the display panel 200. Moreover, the light blocking member 350 may absorb or reflect the incident light.

According to another embodiment of the inventive concept, the light blocking member 350 may omit the cover member 300. That is, when using the above-described adhesive tape 340, which includes the polymer beads Bd, the light blocking member 350 may be omitted.

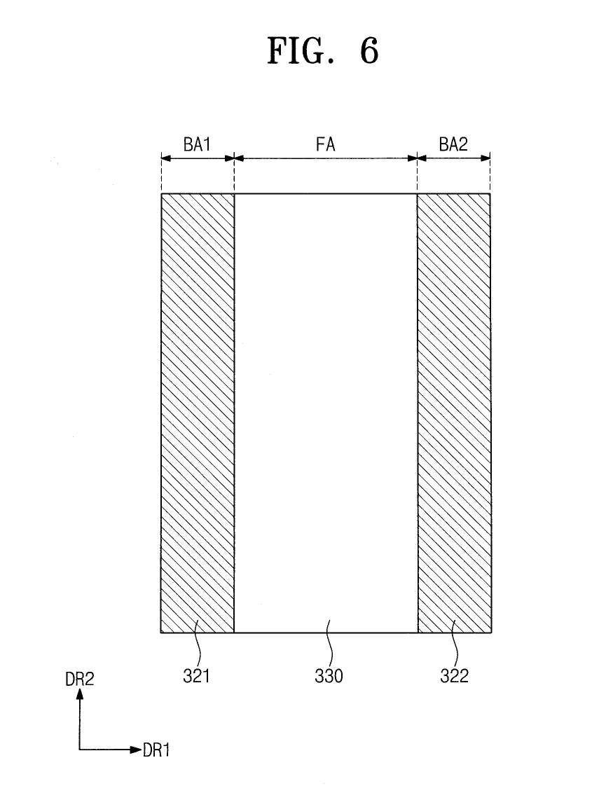

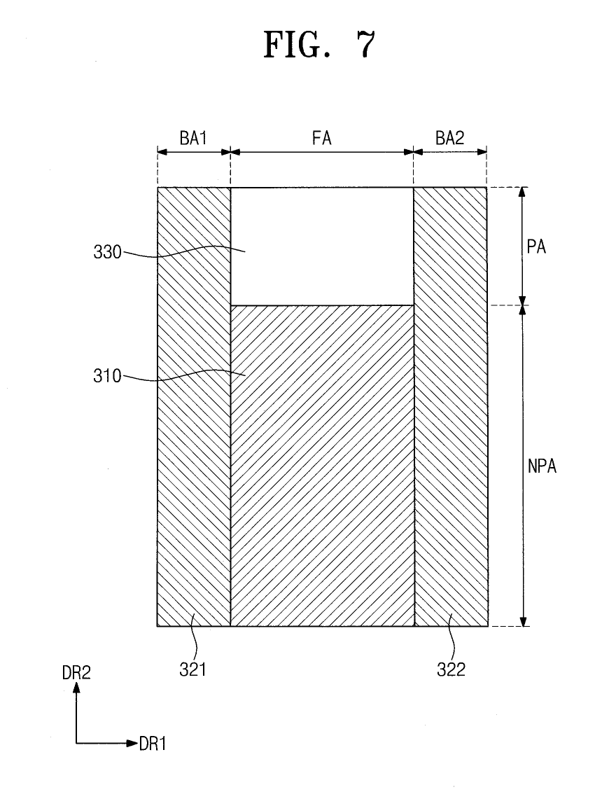

FIG. 6 is a plan view illustrating a rear surface of a module according to one or more example embodiments of the inventive concept, in which the shock absorbing member 310, the curved shock absorbing members 321 and 322, and the hard coating member 330 illustrated in FIG. 4 are coupled. FIG. 7 is a plan view illustrating a rear surface of a module according to one or more example embodiments of the inventive concept, in which the shock absorbing member 310, the curved shock absorbing members 321 and 322, and the hard coating member 330 illustrated in FIG. 4 are coupled.

Referring to FIGS. 4 to 6, according to one or more example embodiment of the inventive concept, the hard coating member 330 may be located below the shock absorbing member 310 and may overlap the entire area of the flat area FA in the display panel 200. That is, the hard coating member 330 may overlap the flat area FA in the display panel 200, but not overlap the first and second curved areas B1 and B2.

Moreover, referring to FIGS. 4 to 7, according to an embodiment of the inventive concept, the hard coating member 330 may partially overlap the flat area FA in the display panel 200. Specifically, the flat area FA may be divided into a disposed area PA that overlaps the printed circuit board PCB, and a non-disposed area NPA that does not overlap the printed circuit board PCB.

In this case, the hard coating member 330 may be located on the disposed area PA that overlaps the printed circuit board PCB. For example, the hard coating member 330 may be located below the flat area FA to overlap the disposed area PA in the flat area FA.

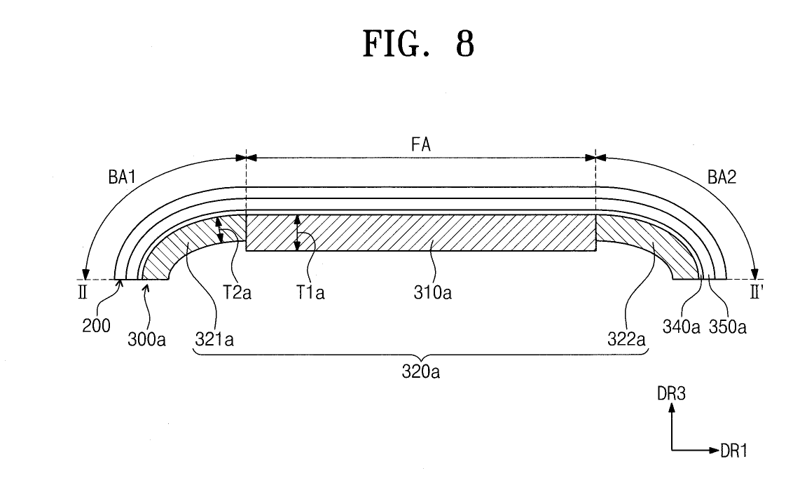

FIG. 8 is a cross-sectional view taken along the line II-II′ in FIG. 2, according to one or more example embodiments of the inventive concept.

Referring to FIGS. 2 and 8, the cross-section illustrated in FIG. 8 excludes the configuration of the window member 100 and the case 400 for convenience of illustration, and is a cross-sectional view illustrating the configuration of the display panel 200 and the cover member 300.

For example, when compared to the display device DD illustrated in FIG. 4, the display device DD illustrated in FIG. 8 may have a different configuration of the cover member 300, but other elements may be substantially the same. Thus, the description about the other elements is omitted.

For example, referring to FIGS. 2 and 8, a cover member 300a includes a flat shock absorbing member 310a, a curved shock absorbing member 320a, an adhesive tape 340a, and a light blocking member 350a.

The shock absorbing member 310a may be located on the rear surface of the display panel 200 and may overlap the flat area FA in the display panel 200. On a plane, the flat shock absorbing member 310a may be formed to have an equal or smaller surface area than the flat area FA and be located on the rear surface of the display panel 200. According to an embodiment, the flat shock absorbing member 310a may have a first thickness T1a.

The flat shock absorbing member 310a may absorb a portion of a shock that is respectively applied to the flat area FA in the display panel 200 and the flat area in the window member 100 (see FIG. 2). Thus, the flat shock absorbing member 310a may prevent or substantially prevent the flat area FA in the display panel 200 and the flat area in the window member 100 from being damaged.

The curved shock absorbing member 320a may include a first curved shock absorbing member 321a and a second curved shock absorbing member 322a, and be located on the same layer as the flat shock absorbing member 310a. The first and second curved shock absorbing members 321a and 322a may respectively overlap the first and second curved areas BA1a and BA2a in the display panel 200.

According to one or more example embodiments, each of the first and second curved shock absorbing members 321a and 322a may have a second thickness T2a. Here, the first thickness T1a may be greater than the second thickness T2a. Moreover, the hardness of the flat shock absorbing member 310a may be greater than the hardness of each of the first and second curved shock absorbing members 321a and 322a.

Likewise, when the printed circuit board PCB is attached to the bottom of the flat shock absorbing member FA, pressure may be applied to the printed circuit board PCB in the third direction DR3. In this case, due to the first thickness T1a of the flat shock absorbing member 310a, the pressure applied in the third direction DR3 to the printed circuit board PCB may not be transferred to the rear surface of the display panel 200. Moreover, due to the hardness of the flat shock absorbing member 310a being formed to be greater than the hardness of each of the first and second curved shock absorbing members 321a and 322a, the pressure applied in the third direction DR3 to the printed circuit board PCB may not be transferred to the rear surface of the display panel 200.

Meanwhile, the hard coating member 330 illustrated in FIG. 4 may also be located below the flat shock absorbing member 310a.

According to one or more example embodiments of the inventive concept, a cover member that includes a hard coating member may be located on the rear surface of a display panel. Consequently, a pressing phenomenon on the rear surface of the display panel in a process of attaching a circuit board to the rear surface of the display panel may be prevented by to the hard coating member.

Therefore, an indentation in the display panel may not be visible from the outside.

As above, example embodiments have been disclosed in the drawings and the specification. Although specific terms are used herein, these terms are used merely for describing the present invention and are not intended to be limiting of the invention as defined by the claims. Thus, it will be understood by one with ordinary skill in the art that various modifications and equivalent embodiments are possible. Therefore, the real protective scope of the present invention shall be determined by the technical scope of the accompanying claims and their equivalents.

What is claimed is:

1. A display device comprising:
a display panel comprising a flat area and a curved area extending from the flat area in a bent manner;
a flat shock absorbing member below the flat area and overlapping the flat area;
a curved shock absorbing member below the curved area and overlapping the curved area; and
a hard coating member below the flat shock absorbing member.

2. The display device of claim 1, further comprising a circuit board below the hard coating member, the circuit board being configured to provide a driving signal to the display panel.

3. The display device of claim 2, wherein the hard coating member partially overlaps the flat area.

4. The display device of claim 2, wherein the flat area comprises:
a display area to display an image; and
a non-display area that is adjacent to the display area, wherein the circuit board overlaps the display area.

5. The display device of claim 1, further comprising a light blocking member below the display panel, wherein a portion of the light blocking member is between the display panel and the flat shock absorbing member, and another portion of the light blocking member is between the display panel and the curved shock absorbing member.

6. The display device of claim 1, further comprising a first adhesive tape between the flat area and the flat shock absorbing member, wherein the first adhesive tape comprises:
a base layer having a top surface and a rear surface;
a first adhesive layer on the top surface, wherein the first adhesive layer comprises a polymer bead; and
a second adhesive layer on the rear surface.

7. The display device of claim 6, further comprising a second adhesive tape connected to the first adhesive tape and located between the curved area and the curved shock absorbing member.

8. The display device of claim 1, wherein the flat shock absorbing member has a first thickness and the curved shock absorbing member has a second thickness, the second thickness being greater than the first thickness.

9. The display device of claim 8, wherein the hard coating member has a third thickness, the first thickness being greater than the third thickness.

10. The display device of claim 1, wherein a hardness of the flat shock absorbing member is greater than a hardness of the curved shock absorbing member.

11. The display device of claim 1, wherein the curved area further comprises a first curved area and a second curved area that are opposite each other, with the flat area therebetween.

12. The display device of claim 11, wherein the curved shock absorbing member further comprises a first curved shock absorbing member below the first curved area and a second curved shock absorbing member below the second curved area.

13. A display device comprising:
a display panel comprising a flat area and a curved area extending from the flat area in a bent manner;
a flat shock absorbing member having a first thickness, the flat shock absorbing member being located below the flat area and overlapping the flat area; and
a curved shock absorbing member having a second thickness, the curved shock absorbing member being located below the curved area and overlapping the curved area,
wherein the first thickness is greater than the second thickness, and a hardness of the flat shock absorbing member is greater than a hardness of the curved shock absorbing member.

14. The display device of claim 13, further comprising a first adhesive tape between the flat area and the flat shock absorbing member, wherein the first adhesive tape comprises:
a base layer having a top surface and a rear surface;
a first adhesive layer on the top surface; and
a second adhesive layer on the rear surface, wherein the first adhesive layer comprises a polymer bead.

15. The display device of claim 14, further comprising a second adhesive tape connected to the first adhesive tape and located between the curved area and the curved shock absorbing member.

16. The display device of claim 13, further comprising a hard coating member below the flat shock absorbing member.

17. The display device of claim 16, wherein the hard coating member partially overlaps the flat area.
